(19) United States
(12) Patent Application Publication
(10) Pub. No.: US 2025/0175148 A1
(43) Pub. Date: May 29, 2025

(54) ACOUSTIC RESONATOR

(71) Applicant: HUAWEI TECHNOLOGIES CO., LTD., Shenzhen (CN)

(72) Inventors: Viktor Plesski, Helsinki (FI); Naiqing Zhang, Shanghai (CN)

(73) Assignee: HUAWEI TECHNOLOGIES CO., LTD., Shenzhen (CN)

(21) Appl. No.: 19/030,568

(22) Filed: Jan. 17, 2025

Related U.S. Application Data
(63) Continuation of application No. PCT/CN2022/129488, filed on Nov. 3, 2022.

(30) Foreign Application Priority Data
Aug. 4, 2022 (WO) PCT/CN2022/110127

(51) Int. Cl. H03H 9/17; H03H 3/02; H03H 9/02; H03H 9/13

(52) U.S. Cl. CPC H03H 9/174; H03H 3/02; H03H 9/02031; H03H 9/02228; H03H 9/132; H03H 9/176; H03H 2003/023

(57) ABSTRACT

An acoustic resonator is provided. The acoustic resonator may comprise a substrate, a piezoelectric membrane attached to the substrate, and a plurality of electrodes. The piezoelectric membrane presents a plurality of grooves, wherein two adjacent grooves define a ridge in between them. Each electrode is placed in a respective groove. Each electrode comprises two lateral parts, each lateral part covering at least partially a respective lateral wall of the groove.

### CROSS-REFERENCE TO RELATED APPLICATIONS

This application is a continuation of International Application No. PCT/CN2022/129488, filed on Nov. 3, 2022, which claims priority to International Application No. PCT/CN2022/110127, filed on Aug. 4, 2022. The disclosures of the aforementioned applications are hereby incorporated by reference in their entireties.

### TECHNICAL FIELD

Embodiments of this application relate to the field of radio communications. In particular, some example embodiments provide an acoustic resonator. In particular, some example embodiments provide a thin-film bulk acoustic resonator device.

### BACKGROUND

Radio frequency (RF) filter for radio communication systems commonly incorporate acoustic resonators.

Some acoustic resonators, such as laterally excited bulk acoustic resonators (XBARs), use suspended piezoelectric crystalline membranes, such as Lithium Niobate (LN) of sub-micron thickness with a horizontal electric field to generate an Al mode resonance with displacement in horizontal direction. However, in the region near top electrodes, the electric field is mainly in vertical direction, which largely mitigates the main resonance mode nearby and hence limits the overall piezo-coupling.

Another drawback is the use of a suspended piezoelectric membrane. Fabrication process required for such devices is difficult as bottom side of the membrane must be open. The bulk acoustic resonators need to be suspended over cavity for acoustic isolation. The devices are fragile as the membranes are very thin. Further, the devices have poor power-handling properties because of low thermal conductivity of the thin piezoelectric membrane made from LN.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

Example embodiments of the present disclosure provide an acoustic resonator. Some embodiments utilize horizontal electric field to excite A1 resonance mode within a thin-film piezoelectric layer as an acoustic resonator.

Some embodiments provide a robust device. The present invention solves the problem of fragility of submicron-thick LN membrane of XBAR resonator by attaching the membrane to a solid thick substrate.

Some embodiments may be manufactured using usual optical lithography, comparable with surface acoustic wave resonators in Mid-High Band (1˜3 GHz range), with minimal critical dimension 350 nm. Some embodiments are suitable for operation at 5 GHz frequency range. Some embodiments may be manufactured using optical lithography.

Some embodiments exhibit excellent power handling capabilities. In some embodiments, the high thermal conductivity substrate provides a heat evacuation path below the piezoelectric membrane, e.g., in a direction perpendicular to the membrane. This avoids overheating and low power handling.

Some embodiments avoid bulk acoustic wave radiation and improve the quality (Q) factor of the resonator by using a high acoustic velocity substrate.

Some embodiments enable strong piezo coupling. In some embodiments, this is achieved by using embedded vertical electrodes generating a uniform horizontal electric field, an appropriate cut for the piezoelectric membrane, an appropriate pitch, and an appropriate geometry of resonator. In some embodiments, a cavity (e.g., groove) in the electrodes enables the piezoelectric ridge to vibrate more freely, increasing the piezo coupling.

Some embodiments comprise vertical U-shaped electrodes to generate a horizontal electric field for A1 mode resonance. This increases the coupling effectively and removes parasitic modes.

Some embodiments provide the possibility to change or tune resonance frequency by changing the pitch and electrode geometry.

Some embodiments comprise an intermediate layer that reduces acoustic coupling between the piezoelectric membrane and the substrate. The intermediate layer decreases the effect from stiff substrate, allows fundamental thickness resonance in the piezoelectric membrane, and thus increases piezo coupling.

The foregoing and other benefits may be achieved by the features of the independent claims. Further implementation forms are apparent from the dependent claims, the description, and the drawings.

According to a first aspect, an acoustic resonator comprises: a substrate; a piezoelectric membrane attached to the substrate, and a plurality of electrodes. The piezoelectric membrane presents a plurality of grooves. Two adjacent grooves define a ridge in between them. Each electrode is placed in a respective one of the grooves. Each electrode comprises two lateral parts, each lateral part covering at least partially a respective lateral wall of the groove.

According to an example embodiment, the acoustic resonator comprises a circuit configured to apply the radio frequency voltage across the at least two electrodes to induce an electric field in the ridge.

According to an example embodiment, the lateral parts of each electrode are electrically connected.

According to an example embodiment, each electrode comprises a bottom part that covers at least partially a bottom of the groove, the bottom part of the electrode being electrically connected to the lateral parts of the electrode.

According to an example embodiment, a cavity is formed in a front surface of each electrode.

According to an example embodiment, a transversal section of the electrode is U-

shaped.

According to an example embodiment, the piezoelectric membrane is attached to the substrate via an intermediate layer.

According to an example embodiment, the intermediate layer is made of SiO2.

According to an example embodiment, a thickness of the intermediate layer is substantially equal to a quarter of wavelength of a shear bulk acoustic wave in the intermediate layer at a resonance frequency of the acoustic resonator.

According to an example embodiment, the substrate is a made of high-acoustic-velocity material, wherein a shear acoustic velocity in the high-acoustic-velocity material is superior to 7000 m/s.

According to an example embodiment, an acoustic velocity in the substrate is at least twice an acoustic velocity in the piezoelectric membrane.

According to an example embodiment, the substrate is a made of diamond, silicon carbide, or boron nitride.

According to an example embodiment, the substrate is mounted on a support wafer.

According to an example embodiment, the support wafer is made of silicon or glass.

According to an example embodiment, a thickness of the substrate is superior to ten times a thickness of the piezoelectric membrane.

According to an example embodiment, a depth of the groove is superior to a third of a thickness of the piezoelectric membrane.

According to an example embodiment, a thickness of the piezoelectric membrane is substantially equal to a half of the wavelength of the shear acoustic wave in the piezoelectric membrane at the operating frequency of the acoustic resonator.

According to an example embodiment, the electrodes are alternatively connected to two busbars, two adjacent electrodes being connected to a different one of the busbars, wherein the circuit is configured to apply the radio frequency voltage across the two busbars.

According to an example embodiment, the busbars are deposited directly on the substrate and do not cover the piezoelectric membrane.

According to an example embodiment, a pitch between two electrodes is smaller than Vₛ/2fᵣ, with Vₛ a shear acoustic velocity in the high acoustic-velocity substrate, and fᵣ an operating frequency of the acoustic resonator.

According to an example embodiment, the piezoelectric membrane is made of a 120°±20° rotated Y-cut of Lithium Niobate or a Z-cut ±20° of Lithium Niobate.

According to a second aspect, a radio frequency filter comprises at least one acoustic resonator according to the first aspect.

Any implementation form may be combined with one or more other implementation forms. These and other aspects of the present disclosure will be apparent from the example embodiment(s) described below.

### DESCRIPTION OF THE DRAWINGS

The accompanying drawings, which are included to aid further understanding of the example embodiments and constitute a part of this specification, illustrate example embodiments and, together with the description, help to explain the example embodiments. In the drawings:

FIG. 1A is a schematic plane top-view of an example acoustic resonator;

FIG. 1B is a schematic plane top-view of another example acoustic resonator;

FIG. 1C is a schematic plane top-view of another example acoustic resonator;

FIG. 2 is a schematic three-dimensional view of a section of an example acoustic resonator;

FIG. 3 is a schematic cross-sectional view of a section of an example acoustic resonator;

FIG. 4 is a schematic exploded cross-sectional view of a section of an example acoustic resonator;

FIG. 5 is a schematic cross-sectional view of a section of another example acoustic resonator;

FIG. 6 is a schematic cross-sectional view of an electrode of another example acoustic resonator;

FIG. 7 shows a resonance vibration mode A1 in a schematic cross-sectional view of a section of an example resonator.

FIG. 8 is a chart of the piezo coupling of an example acoustic resonator as a function of thickness of the intermediate layer;

FIG. 9 is a chart of the piezo coupling of an example acoustic resonator as a function of depth of the cavity in the electrodes;

FIG. 10 is a chart of the admittance of an example acoustic resonator as a function of frequency;

FIG. 11A and FIG. 11B are charts of the admittance of two different example acoustic resonators as a function of frequency;

FIG. 12 is a flow chart of an example process for fabricating an example acoustic resonator;

Like references are used to designate like parts in the accompanying drawings.

### DETAILED DESCRIPTION

Reference will now be made in detail to example embodiments, examples of which are illustrated in the accompanying drawings. The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

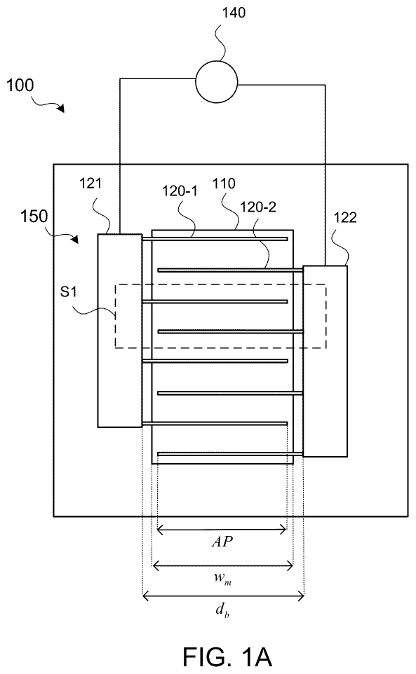

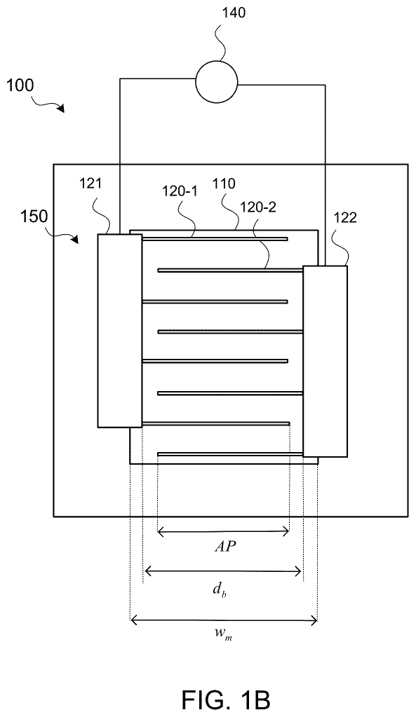

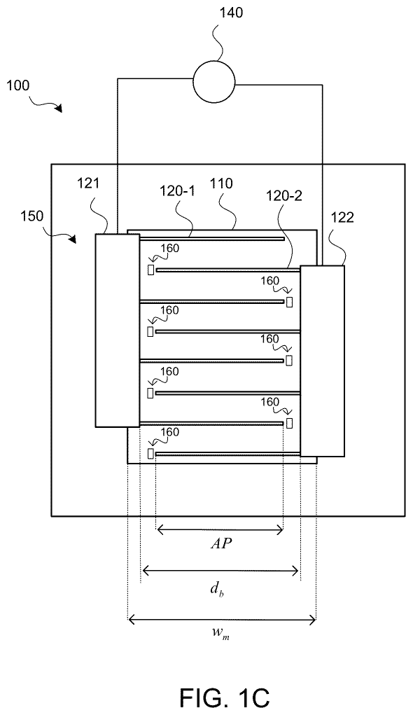

FIG. 1A shows a schematic plan view of an example acoustic resonator 100. Resonators such as the resonator 100 may be used in a variety of RF filters including band-reject filters, band-pass filters, duplexers, and multiplexers.

The resonator 100 comprises a piezoelectric membrane 110, and at least two electrodes 120-1, 120-2. The electrodes 120-1, 120-2 are in contact with the piezoelectric membrane 110. A circuit 140 may be configured to apply a radio frequency voltage across two adjacent electrodes 120-1, 120-2. As such, two adjacent electrodes 120-1, 120-2 have opposite polarities.

In some embodiments, the resonator 100 includes an interdigital transducer (IDT) 150. The IDT 150 includes a first plurality of parallel electrodes or electrode fingers, such as electrode 120-1, connected to a first busbar 121 and a second plurality of electrodes or electrode fingers, such as electrode 120-2, connected to a second busbar 122. The first and second pluralities of parallel electrodes are interleaved (or interdigitated). Two adjacent electrodes 120-1, 120-2 are connected to a different busbar 121, 122. The interleaved electrodes 120-1, 120-2 overlap for a distance AP, commonly referred to as the aperture of the IDT. The busbars 121, 122 are separated by a distance db. The distance de between the busbars 121, 122 is larger than the aperture AP of the IDT. In some embodiments, the overlapping part of the electrodes is situated on the piezoelectric membrane 110, while the busbars 121, 122 are positioned either directly on the substrate 102 or on the intermediate layer 103, but not on the piezoelectric membrane 110.

The resonator 100 may comprise two terminals. The resonator 100 has low impedance at resonance frequency and high impedance at anti-resonance frequency. The first and second busbars 121, 122 may serve as the terminals of the resonator 100. In that case, the radio frequency signal is applied between the two busbars 121, 122 of the IDT 130.

The primary direction of the electric field created between two electrodes is in the plane of the piezoelectric membrane 110. In that sense, the electric field in the piezoelectric membrane 110 may be considered horizontal.

The radio frequency signal excites a primary acoustic mode within the piezoelectric membrane 110. The primary acoustic mode may be A1 Lamb mode or close to A1 Lamb mode. The primary acoustic mode may be a shear mode where the major displacements at resonance are shear vibrations within the piezoelectric membrane 110 with mainly horizontal displacements in the regions between electrodes, with an amplitude of the displacements changing in the membrane thickness direction. Meanwhile, near onset frequency the primary acoustic mode (e.g., A1 Lamb mode) is mainly composed of two shear bulk waves in which acoustic energy is bouncing up and down in the membrane thickness direction. The waves are shear in the sense that the displacements in the wave are perpendicular to the direction of propagation of the wave. The direction of propagation is vertical, and the direction of displacement is horizontal. Due to anisotropy of piezo effect, the horizontal electric field excites the waves bouncing up and down. At resonance the displacements are in opposite phase at top and bottom sides of membrane if the membrane thickness is λ/2. The amplitude of the displacements changes along the thickness direction. The shear deformations and shear stresses are created by horizontal electric field due to corresponding piezo-module (e.g., piezo-module e15).

The primary acoustic mode or main resonance mode is similar to A1 Lamb mode. A resonance frequency fᵣ of the primary acoustic mode depends on a thickness tₚ of the piezoelectric membrane and on a pitch p (i.e., a spacing between two electrodes 120-1, 120-2). More specifically,

$${f}_{r} = \sqrt{{( \frac{{v}_{z}}{2 {t}_{p}} )}^{2} + {( \frac{{v}_{x}}{2 p} )}^{2}}$$

with, V_{z} a transverse acoustic velocity in the piezoelectric material in the thickness (Z) direction, and vₓ a longitudinal acoustic velocity in the piezoelectric material in the horizontal (X) direction.

The piezoelectric membrane 110 may or may not extend under the busbars 121, 122 of the IDT 130.

In some embodiments, as shown in FIG. 1A, the piezoelectric membrane 110 does not extend under the busbars 121, 122 of the IDT 130. As shown in FIG. 1A, a width wm of the piezoelectric membrane 110 may be greater or equal to the aperture AP of the IDT, but less than the distance db between the busbars 121, 122 of the IDT 130. This isolates the main resonance region from busbars 121, 122 on both sides, suppressing the transversal mode to a large extent.

In some embodiments, as shown in FIG. 1B, the piezoelectric membrane 110 extends (e.g., partially, or fully) under the busbars 121, 122 of the IDT 130. In that case, the width wm of the piezoelectric membrane 110 may be greater than the distance db between the busbars 121, 122 of the IDT 130.

In some embodiments, as shown in FIG. 1C, the piezoelectric membrane 110 may present holes 160 between the tips of the electrodes 120-1, 120-2 and the busbars 121, 122. The holes 160 can have rectangular, circular or other form. In that case, the piezoelectric membrane 110 may or may not extend under the busbars 121, 122 of the IDT 130. The holes 160 reduce acoustic energy loss in transverse (aperture) direction. The holes 160 may be formed by deleting (e.g., etching) the piezoelectric membrane 110 in an area between the busbars 121, 122 and electrodes 120. The holes 160 isolate the main resonance region from busbars 121, 122 on both sides, suppressing the transversal mode to a large extent.

The piezoelectric membrane is made of piezoelectric material, such as Lithium Niobate (LN), Lithium Tantalate (LT), Al(Sc) N, ZnO.

The electrodes 120-1, 120-2 may be aluminium, substantially aluminium alloys, copper, substantially copper alloys, beryllium, gold, tungsten, molybdenum or some other conductive material. The busbars 121, 122 of the IDT may be made of the same or different materials as the electrodes. Busbars can have double or second metallization for reduction of their resistivity.

FIG. 2 shows a schematic three-dimensional view of a section of an example acoustic resonator 100. In particular, FIG. 2 shows a schematic three-dimensional view of a section S1 of the example acoustic resonator 100 of FIG. 1A.

A thickness tp of the piezoelectric membrane 110 may be substantially equal to a half of the wavelength of a shear acoustic wave in the piezoelectric membrane 110 at the operating frequency fr of the acoustic resonator 100 propagating in the thickness direction (0Z) with displacements in horizontal direction (0X). In some embodiments, the thickness tp may be, for example, 400 nm. The effect of the thickness of the intermediate layer is described in more details in relation to FIG. 8.

The piezoelectric membrane 110 may have different component values of piezoelectric tensors with different crystal orientations. The piezoelectric tensor components describe excitation of a requested mode of resonance vibration by applied electric field (e.g., e15 for A1 mode, in XBAR-type structure, e16 for SH0 mode in I.H.P.—type devices). Usually, the specific piezoelectric tensor component should be large and other components should be small to avoid generation of parasitic modes. In particular, the piezoelectric membrane 110 may be 120°±20° rotated Y-cut or a Z-cut ±20°, Y-propagation. In some embodiments, 120°±20° rotated Y-cut may provide a maximum piezo-coupling based on the embedded vertical electrode structure and resonance mode (A1), with large corresponding piezo-module (e.g., e15). Z-cut ±20° may be an alternative orientation, in particular for a little weaker coupling.

The cut may be optimized for getting necessary magnitude of the piezoelectric tensor components. The cut determines the magnitude of piezo-coupling and, at the end, the relative width of the filter passband (e.g., ladder-type filter passband).

The resonator 100 comprises a substrate 102. The substrate 102 provides mechanical support to the piezoelectric membrane 110.

The piezoelectric membrane 110 is attached to the substrate 102. In other words, the piezoelectric membrane 110 is solidly mounted on the substrate 102

The piezoelectric membrane 110 has parallel front and back surfaces. The front side is the surface facing away from the substrate 102. The back side is the surface facing the substrate 102. The back surface of the piezoelectric membrane 110 is attached to the substrate 102, or the intermediate layer 103.

The substrate 102 may be made of high-acoustic-velocity material. A shear acoustic velocity of the high-acoustic-velocity material is typically superior to 7000 m/s. For example, the acoustic velocity Vₛ of the substrate 102 may be at least twice an acoustic velocity Vₚ of the piezoelectric membrane 110. For example, the substrate 102 may be made of diamond, silicon carbide, boron nitride, or some other material or combination of materials with high acoustic velocity.

The substrate 102 with high velocity prevents bulk acoustic wave from leaking into the substrate 102, when the pitch between the electrodes 120-1 and 120-2 is smaller than

$$\frac{{t}_{p} * {V}_{s}}{{V}_{p}} ,$$

with tₚ the thickness of the piezoelectric membrane, Vₛ the acoustic velocity of the substrate 102, Vₚ of the acoustic velocity of the piezoelectric membrane 110. Such a robust substrate provides excellent power handling capability for the resonator due to efficient evacuation of the heat generated mainly in the electrodes to the substrate with high thermal conductivity.

The substrate 102 may be mounted on a support wafer 101. The support wafer 101 may, for example, be made of silicon or glass. The support wafer 101 provides mechanical stability and good heat evacuation.

The substrate 102 can be a relatively thin layer. However, it needs to be sufficiently thick in relation to the piezoelectric membrane 110, such that A1 mode vibrations are completely constrained in the piezoelectric membrane 110 and strongly attenuate to the support wafer. For example, a thickness of the substrate 102 may be superior to ten times the thickness of the piezoelectric membrane 110. This reduces or avoids bulk acoustic radiation into the support wafer and improve quality factor or Q-factor of the resonator.

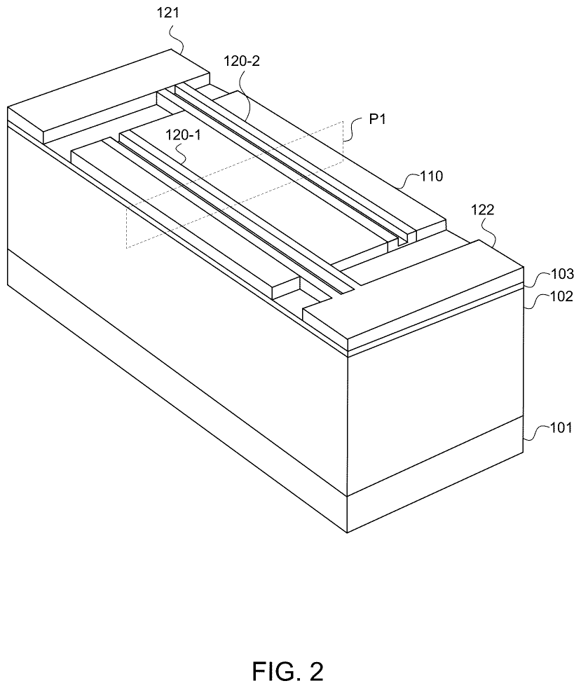

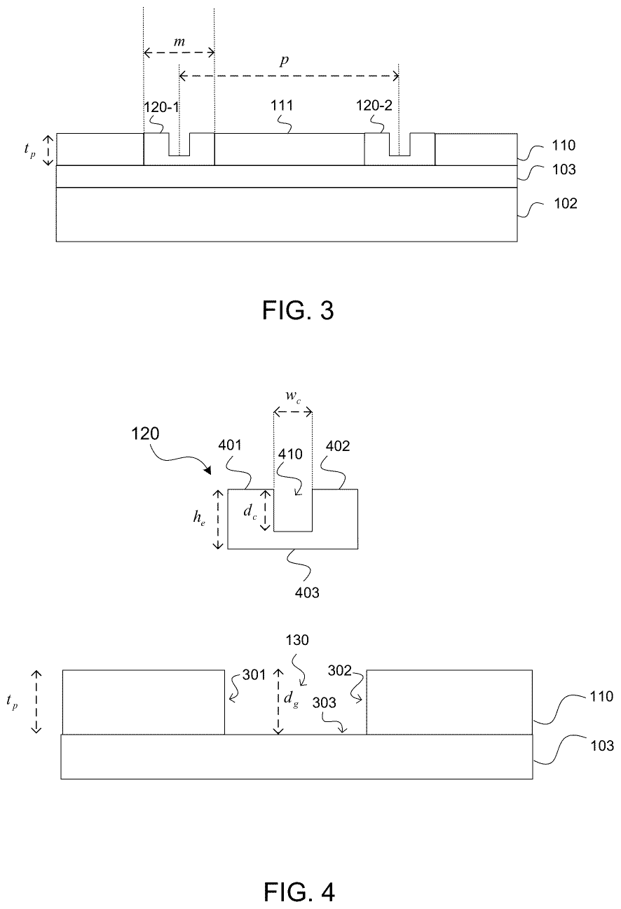

The back surface of the piezoelectric membrane 110 (e.g., with intermediate layer 103 underneath) may be bonded to the substrate 102 using a wafer bonding process. Alternatively, the piezoelectric membrane 110 may be grown on the substrate 102 or attached to the substrate in some other manner. The piezoelectric membrane 110 may be attached directly to the substrate or may be attached to the substrate via one or more intermediate material layers (e.g., intermediate layer 103 of FIG. 3).

FIG. 3 shows a schematic cross-sectional view of a section of an example resonator. In particular, FIG. 3 shows a schematic two-dimensional view of a plane P1 of the example acoustic resonator 100 of FIG. 2. The resonator 100 may comprise a periodic repetition of parallel and regularly spaced sections similar to the section illustrated by FIG. 4.

The piezoelectric membrane 110 may be attached to the substrate 102 via an intermediate layer 103. A thickness of the intermediate layer 103 may be substantially equal to a quarter of wavelength of a shear bulk acoustic wave in the intermediate layer 103 at a resonance frequency of the acoustic resonator. The intermediate layer 103 (e.g., with λ/4 thickness) reduces acoustic coupling between the piezoelectric membrane 110 and the substrate 102, thereby increasing the piezo coupling. The intermediate layer 103 may be made of SiO2. The SiO2 layer decreases the effect from the stiff substrate, allows fundamental thickness resonance in the piezoelectric membrane 110, and thus further increases piezo coupling. The busbars are deposited either on the intermediate layer 103, or on the substrate 102. In some embodiments, less preferred, the busbars may also be deposited on the piezoelectric layer 110.

FIG. 4 is a schematic exploded cross-sectional view of a section of an example acoustic resonator.

A plurality of grooves 130 are formed in the front surface of the piezoelectric

membrane 110. A groove 130 may be a long, narrow cut or depression in the piezoelectric membrane 110.

As illustrated by FIG. 3, two adjacent grooves 130 define a ridge 111 in between them.

A transversal section of the groove 130 may be a rectangle, or have a different shape, such as a regular or irregular polygon. The groove may have a bottom wall 303 and two side walls 301, 302. The side walls 301, 302 of the grooves may be straight, inclined, or curved.

The grooves 130 may extend partially or completely through the piezoelectric membrane 110. The depth d_{g} of the grooves 130 formed in the piezoelectric membrane 110 may be less than, equal to, or greater than the thickness tₚ of the piezoelectric membrane. In some embodiments, the depth d_{g} of the groove 130 may be superior to a third of a thickness tₚ of the piezoelectric membrane. In some embodiments, the depth d_{g} of the groove 130 may be in a range of 150 nm to 250 nm

As illustrated by FIG. 5, if the depth d_{g} of a groove is greater than the thickness tₚ of the piezoelectric membrane, the groove may extend in the intermediate layer 103.

The grooves 130 may be formed, for example, by selective etching of the piezoelectric membrane 110 before or after the piezoelectric membrane 110 and the substrate 102 are attached.

As illustrated by FIG. 3, each electrode 120-1, 120-2 is placed in a respective groove 130.

A total width m of the electrode 120-1 or 120-2 is equal to the width of the groove 130. The pitch p is the spacing (e.g., centre-to-centre spacing) between two electrodes 120-1, 120-2. m/p is a metallization ratio of the resonator.

In some embodiments, the pitch p is smaller than Vₛ/2fᵣ (1), with vₛ the shear acoustic velocity of the substrate, and fᵣ the operating frequency of the acoustic resonator.

In some embodiments, the pitch p is smaller than

$$\frac{{V}_{s} * {t}_{p}}{{V}_{m}} , \qquad ( 2 )$$

where Vₛ is the sound velocity in the substrate and Vₘ the sound velocity in the piezoelectric membrane, tₚ the thickness of the piezoelectric membrane.

The velocity of sound may be around 4000 m/s in the piezoelectric membrane, and as high as 9600 m/s in the high-sound-velocity substrate. Hence, in case of the diamond substrate, the pitch is smaller than 2.4 times the thickness tp of the piezoelectric membrane 110. This enables a frequency fᵣ of the acoustic resonator as high as 5 GHz with a pitch p smaller than 1.2 μm. Such a pitch p is suitable for manufacturing with optical lithography. Such a pitch p avoids or at least significantly limits bulk acoustic wave radiation into the bottom substrate.

Formula (1), and (2) are only reasonable estimates. Device simulation (e.g., based on finite element methods (FEM) may be used to determine exactly if the pitch is sufficiently small to avoid the bulk wave radiation into substrate.

The electrodes 120-1, 120-2 extend perpendicular to the surface of the piezoelectric membrane 110. In that sense, the electrodes 120-1, 120-2 may be considered vertical. The vertical electrodes enable the horizontal electric field for A1 mode resonance. As such, the vertical electrodes increase the piezo coupling effectively and removes parasitic modes.

As illustrated by FIG. 4, an electrode 120 may be attached onto the side walls of the piezoelectric membrane. The electrode 120 may be contiguous with the side walls 301, 302 of the groove 130 over substantially all or part of the side walls 301, 302 of groove 130. In particular, the electrode 120 may be contiguous with the side walls 301, 302 of the groove 130 over at least 50% of the side walls 301, 302 of groove 130.

As illustrated by FIG. 3, the radio frequency voltage applied across two adjacent electrodes 120-1, 120-2 induces an electric field in the ridge 111 defined in between the two adjacent electrodes 120-1, 120-2.

The electrodes 120-1, 120-2 are vertically embedded in the piezoelectric membrane 110. This provides uniform horizontal electric fields through the piezoelectric membrane 110, inside the ridge 111, offering optimal excitation of A1 mode resonance. This helps increase the piezo-coupling and reduce parasitic modes.

As illustrated by FIG. 4, the electrode 120 has front and back surfaces. The front surface is the surface facing away from the piezoelectric membrane 110. The back surface is the surface facing the piezoelectric membrane 110. The back surface of the electrode 120 is attached to the piezoelectric membrane 110.

In some embodiments, a height heof the electrodes 120 may be in a range of 150 nm to 250 nm. The height of the busbars (121, 122 in FIG. 1A, FIG. 1B, FIG. 1C) of the IDT may be the same as, or greater than, the height of the electrodes 120.

In some embodiments, the front surface of the electrode 120 presents a cavity 410, FIG. 4. The cavity 410 in the electrodes 120 enables the ridge 111 to vibrate more freely, increasing the piezo coupling.

A separate cavity 410 is formed in each electrode 120. The cavity 410 in the electrode 120 may be formed be depositing the electrode 120 only on the side walls of the groove 130 (and optionally on the bottom wall of the grove). Alternatively, the cavities 410 in the electrode 120 may be formed by removing excess metal, for example, by etching through patterned photoresist.

The cavity 410 may be a groove, such as a long, narrow cut or depression in the electrode 120. The cavity 410 in the electrode 120 may be a groove that is substantially parallel to the groove 130 in the piezoelectric membrane 110 in which the electrode 120 is placed. The cavity 410 in the electrode 120 extends substantially all along the length of the electrode 120. In particular, the cavity 410 may extend along more than 90% of the length of the electrode 120, at least in the area of the aperture AP of the electrodes (e.g., FIG. 1A).

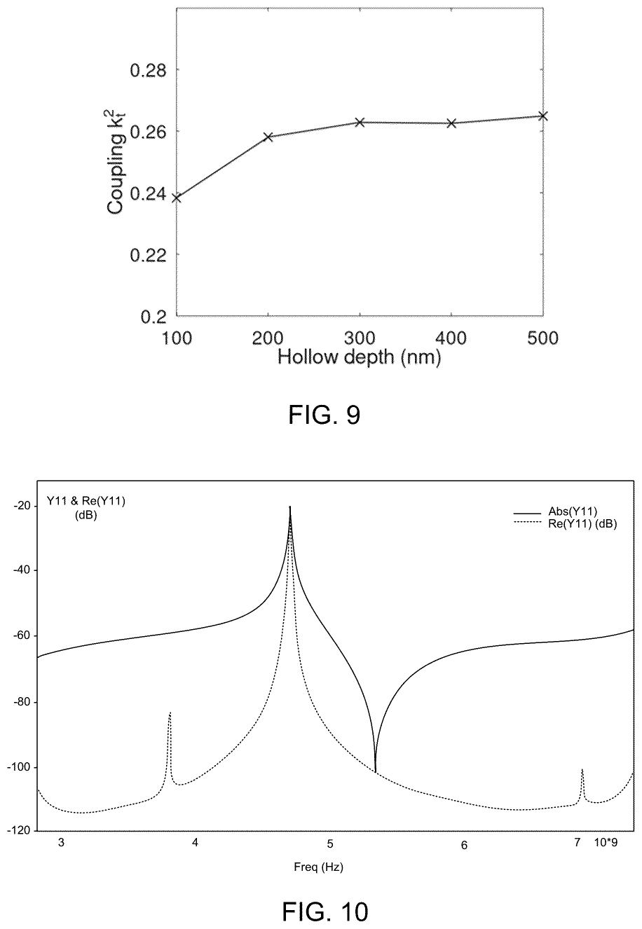

The cavity 410 may extend partially or completely through the electrode 120. The depth d_{c} of the cavity formed in the electrode 120 may be less than, equal to or greater than the height hₑ of the electrode 120. In some embodiments, the depth d_{c} of the cavity formed in the electrode 120 is superior to two third of a height hₑ of the electrode 120. This enables a high piezo coupling. In some embodiments, a depth d_{c} of the cavity 410 in the electrodes 120 may be in a range of 100 nm to 250 nm. In some embodiments, a width w_{c} of the cavity 410 in the electrodes 120 may be in a range of 50 nm to 100 nm. The effect of the depth of the cavity in the electrodes is described in more details in relation to FIG. 9.

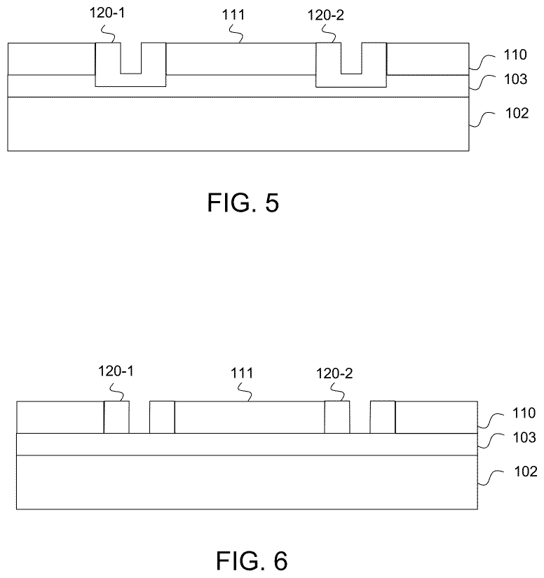

As illustrated on FIG. 4, the transversal section of the electrode 120 may be U-shaped. The electrode 120 may comprise a first lateral part 401, and a second lateral part 402. The first lateral part 401 and a second lateral part 402 are separated by the cavity 410. The electrode 120 may additionally comprise a bottom part 403. As illustrated by FIG. 6, the electrode 120 may not comprise a bottom part 403.

As illustrated by FIG. 4, each lateral part 401 covers at least partially a respective lateral wall of the groove 130. The first lateral part 401 covers at least partially the side wall 301 of the groove. The second lateral part 402 covers at least partially the side wall 302 of the groove 130. The electrode 120 may additionally comprise a bottom part 403 covering at least partially the bottom wall 303 of the groove.

The lateral parts 121, 122 of the electrode 120 are electrically connected. The lateral parts 121, 122 may be connected by the bottom part 403. Alternatively, or in addition, the lateral parts 121, 122 may be connected by one of the busbars (121, 122 in FIG. 1A, FIG. 1B, FIG. 1C) of the IDT.

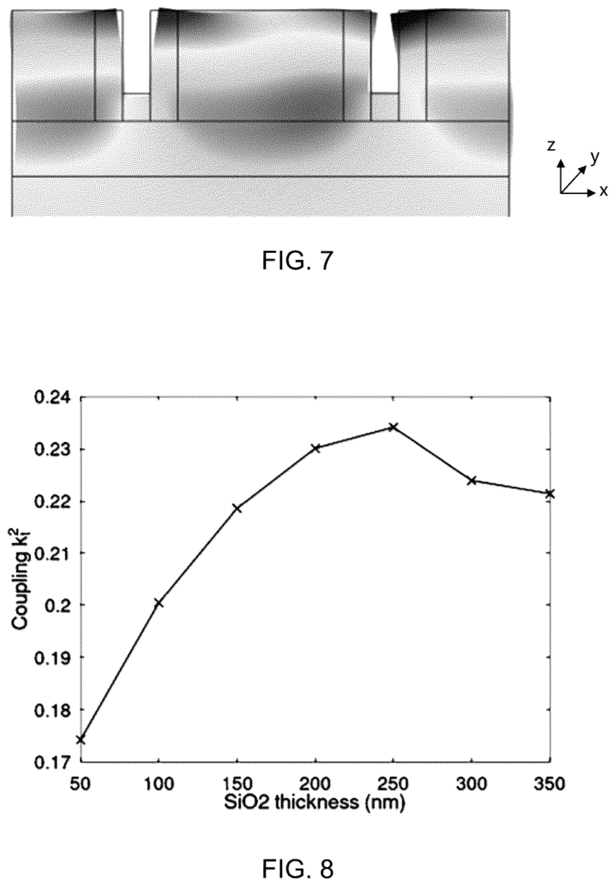

FIG. 7 shows a resonance vibration mode in a schematic cross-sectional view of a section of an example resonator. The resonance vibration mode is close to antisymmetric Lamb mode A1 in the piezoelectric membrane. In the illustrated example, the piezoelectric membrane is made of 120° Y-cut of LN, a thickness of 400 nm, a pitch p of 0.9 um, and a metallization ratio m/p=0.33.

A1 Lamb mode has main vibration displacement in horizontal direction x. The displacements are in opposite directions on top and bottom side of the membrane. The displacements are generated by the horizontal electric field. The selected cut of LN membrane provides high value of piezo-module (e.g., piezo-module e15). The piezo-module is responsible for generating stresses (e.g., S5=S13), which excite the

$$\frac{λ}{2} = t$$

shear wave thickness resonance at corresponding frequency.

Vertical electrodes provide uniform horizontal electric fields near electrodes area, rather than vertical electric fields as electrodes on top of the piezoelectric membrane would, offering larger coupling and weaker parasitic modes. The high-velocity substrate allows avoiding bulk wave radiation and energy leakage downwards. All acoustic energy is trapped in the piezoelectric membrane, and, partially, in the intermediate layer providing a high Q factor to the resonator.

FIG. 8 is a chart of the piezo coupling of an example acoustic resonator as a function of thickness of the intermediate layer.

In the example the intermediate layer is made of SiO2, the piezoelectric membrane is made of LN, and the substrate of diamond. The intermediate layer made of SiO2 reduces acoustic coupling between LN and diamond. The coupling is at its maximum, ˜23%, when the intermediate layer thickness is about a half of the thickness of the piezoelectric membrane. The shear wave velocities in LN and SiO2 are comparable, therefore, in other words, the intermediate layer thickness is about a quarter of shear wave wavelengths in its material. In the illustrated example, 200 nm for the thickness of the intermediate layer, and 400 nm for the thickness of the piezoelectric membrane. An intermediate layer having a thickness of about half the thickness of the piezoelectric membrane largely decreases the acoustic effect from stiff diamond substrate, allows fundamental A1 mode resonance in LN, and hence increases piezo coupling.

FIG. 9 is a chart of the piezo coupling of an example acoustic resonator as a function of depth of the cavity (or hollow depth) in the electrodes.

In some embodiments, the depth d_{c} of the cavity formed in the electrode 120 is superior to one third of a thickness tₚ of the piezoelectric membrane 110. Such a cavity 410 in the electrodes 120 enables the ridge 111 to vibrate more freely in horizontal direction and thus increase the piezo coupling. For example, for a thickness tₚ of the piezoelectric membrane 110 of 600 nm, the depth d_{c} of the cavity formed in the electrode 120 may be superior to 200 nm. This enables a large coupling K2 (˜26%).

FIG. 10 is a chart of the admittance of an example acoustic resonator as a function of frequency. The admittance curve for optimized structure parameters, shows large coupling (26.4%), parasitic-mode-free, high-frequency (4.5-6 GHz) configuration. It implies the validity and correctness of the model to further practical fabrication.

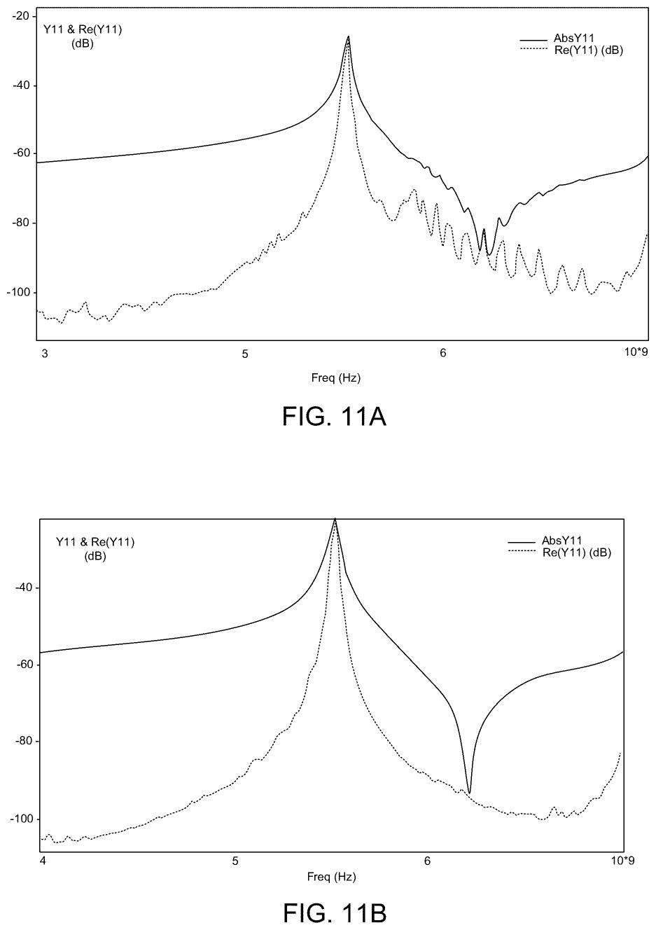

FIG. 11A and FIG. 11B are charts of the admittance as a function of frequency of two different example acoustic resonators. In the example resonator of FIG. 11A, the busbars 121, 122 cover the piezoelectric membrane 110, whereas, in the example resonator of FIG. 11B, the busbars 121, 122 do not cover the piezoelectric membrane 110. The comparison of FIG. 11A and FIG. 11B shows that isolating the piezoelectric membrane 110 from busbars 121, 122 on both sides suppresses the transversal mode to a large extent.

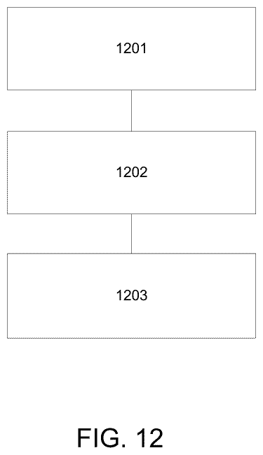

FIG. 12 is a simplified flow chart showing an example process 1200 for making a resonator or a filter incorporating a resonator. The flow chart of FIG. 12 includes only major process steps. Additional steps, including various conventional process steps (e.g., surface preparation, cleaning, inspection, baking, annealing, monitoring, testing, etc.) may be performed before, between, after, and during the steps shown in FIG. 12.

At operation 1201, the piezoelectric membrane 110 is bonded to the substrate 102. The piezoelectric membrane 110 and the substrate 102 may be bonded by a wafer bonding process. One or more intermediate layers 103 may be formed or deposited on the surface of one or both of the piezoelectric membrane 110 and the substrate 102.

At operation 1202, the grooves 130 are formed in the piezoelectric membrane 110. A separate groove 130 may be formed for each electrode 120. The grooves 130 may be formed using conventional photolithographic and etching techniques.

At operation 1203, the electrodes 120 are formed by depositing one or more conductor layer in the grooves 130 formed in the piezoelectric membrane 110. The conductor layer may be, for example, aluminium, an aluminium alloy, copper, a copper alloy, or some other conductive metal.

A separate cavity 410 is formed in each electrode 120. The cavity 410 in the electrode 120 may be formed be depositing the electrode 120 only on the side walls of the groove 130 (and optionally on the bottom wall of the grove). Alternatively, the cavities 410 in the electrode 120 may be formed by removing excess metal, for example, by etching through patterned photoresist. The conductor layer can be etched, for example, by plasma etching, reactive ion etching, wet chemical etching, and other etching techniques.

Any range or device value given herein may be extended or altered without losing the effect sought. Also, any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The steps or operations of the methods described herein may be carried out in any suitable order, or simultaneously where appropriate. Additionally, individual blocks may be deleted from any of the methods without departing from the scope of the subject matter described herein. Aspects of any of the example embodiments described above may be combined with aspects of any of the other example embodiments described to form further example embodiments without losing the effect sought.

The term “comprising” is used herein to mean including the method, blocks, or elements identified, but that such blocks or elements do not comprise an exclusive list and a method or apparatus may contain additional blocks or elements.

Although subjects may be referred to as ‘first’ or ‘second’ subjects, this does not necessarily indicate any order or importance of the subjects. Instead, such attributes may be used solely for the purpose of making a difference between subjects.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from scope of this specification.

What is claimed is:

1. An acoustic resonator comprising:
a substrate;
a piezoelectric membrane attached to the substrate, wherein the piezoelectric membrane includes a plurality of grooves, wherein two adjacent grooves define a ridge in between them; and
a plurality of electrodes, wherein each electrode is placed in a respective groove from the plurality of the grooves, each electrode comprises two lateral parts, and each lateral part covers at least partially a respective lateral wall of the groove.

2. The acoustic resonator according to claim 1, wherein the lateral parts of each electrode are electrically connected.

3. The acoustic resonator according to claim 1, further comprising: a circuit, configured to apply a radio frequency voltage across the plurality of electrodes placed in the adjacent grooves to induce an electric field in the ridge.

4. The acoustic resonator according to claim 1, wherein each electrode comprises a bottom part that covers at least partially a bottom of the groove, and the bottom part of the electrode is electrically connected to the lateral parts of the electrode.

5. The acoustic resonator according to claim 1, wherein a cavity is formed in a front surface of each electrode.

6. The acoustic resonator according to claim 1, wherein a transversal section of each electrode is U-shaped.

7. The acoustic resonator according to claim 1, wherein the piezoelectric membrane is attached to the substrate via an intermediate layer.

8. The acoustic resonator according to claim 7, wherein the intermediate layer is made of SiO2.

9. The acoustic resonator according to claim 6, wherein a thickness of the intermediate layer is substantially equal to a quarter of wavelength of a shear bulk acoustic wave in the intermediate layer at a resonance frequency of the acoustic resonator.

10. The acoustic resonator according to claim 1, wherein the substrate is made of high-acoustic-velocity material, wherein a shear acoustic velocity in the high-acoustic-velocity material is superior to 7000 m/s.

11. The acoustic resonator according to claim 1, wherein an acoustic velocity in the substrate is at least twice an acoustic velocity in the piezoelectric membrane.

12. The acoustic resonator according to claim 1, wherein the substrate is made of diamond, silicon carbide, or boron nitride.

13. The acoustic resonator according to claim 1, wherein a thickness of the substrate is more than ten times a thickness of the piezoelectric membrane.

14. The acoustic resonator according to claim 1, wherein a depth of the groove is more than a third of a thickness of the piezoelectric membrane.

15. The acoustic resonator according to claim 1, wherein a thickness of the piezoelectric membrane is substantially equal to a half of the wavelength of the shear acoustic wave in the piezoelectric membrane at the operating frequency of the acoustic resonator.

16. The acoustic resonator according to claim 1, wherein the electrodes are alternatively connected to two busbars, and two adjacent electrodes are connected to a different one of the busbars.

17. The acoustic resonator according to claim 1, wherein the piezoelectric membrane covers only an area defined by an overlapping of the electrodes.

18. The acoustic resonator according to claim 1, wherein a pitch between two electrodes is smaller than Vₛ/2fᵣ, wherein Vₛ is a shear acoustic velocity in the substrate, and fᵣ is an operating frequency of the acoustic resonator.

19. The acoustic resonator according to claim 1, wherein the piezoelectric membrane is made of a 120°±20° rotated Y-cut of Lithium Niobate or a Z-cut ±20° of Lithium Niobate.

20. A radio frequency filter comprising at least one acoustic resonator which comprises:
a substrate;
a piezoelectric membrane attached to the substrate, wherein the piezoelectric membrane includes a plurality of grooves, wherein two adjacent grooves define a ridge in between them; and
a plurality of electrodes, wherein each electrode is placed in a respective groove from the plurality of the grooves, each electrode comprises two lateral parts, and each lateral part covers at least partially a respective lateral wall of the groove.
